(19) United States
(12) Patent Application Publication
(10) Pub. No.: US 2026/0248054 A1
(43) Pub. Date: Aug. 20, 2026

(54) SEMICONDUCTOR MODULE

(71) Applicant: FUJI ELECTRIC CO., LTD., Kawasaki-shi (JP)

(72) Inventors: Toshio DENTA, Matsumoto-city (JP); Takahiro KOMATSU, Matsumoto-city (JP)

(73) Assignee: FUJI ELECTRIC CO., LTD., Kawasaki-shi (JP)

(21) Appl. No.: 19/536,629

(22) Filed: Feb. 11, 2026

(30) Foreign Application Priority Data
Feb. 20, 2025 (JP) 2025-025711
Jan. 14, 2026 (JP) 2026-004100

(51) Int. Cl. H10W 90/00; H10W 40/22; H10W 74/10

(52) U.S. Cl. CPC H10W 90/734; H10W 40/22; H10W 74/117; H10W 90/701; H10W 90/756

(57) ABSTRACT

A semiconductor module includes an accommodating member having a first main surface and a second main surface that face opposite directions, and a side surface between the first main surface and the second main surface; a mounting substrate accommodated in the accommodating member; a semiconductor chip mounted to the mounting substrate; and a connection terminal protruding from the side surface. The second main surface includes a base surface in which an opening is formed; and a first stepped surface positioned between the base surface and the side surface in plan view and recessed toward the first main surface with respect to the base surface. The mounting substrate has a heat dissipation surface positioned inside the opening, and a first groove recessed toward the first main surface and extending in an extending direction of the side surface is formed in the first stepped surface.

### CROSS REFERENCE TO RELATED APPLICATION

This Application is based on, and claims priority from, Japanese Patent Application No. 2025-025711, filed February 20, 2025, and Japanese Patent Application No. 2026-004100, filed January 14, 2026, the entire contents of which are incorporated herein by reference.

### BACKGROUND

### Field of the Invention

The present disclosure relates to semiconductor modules.

### Description of Related Art

A semiconductor module having a structure in which a plurality of connection terminals protrudes from a housing portion has been proposed (Japanese Patent Application Laid-Open Publication No. 2022-131370, International Patent Publication No. WO 2023/210379, Japanese Patent No. 6752381, Japanese Patent Application Laid-Open Publication No. 2007-73743, and International Patent Publication No. WO 2017/175612). For example, Japanese Patent Application Laid-Open Publication No. 2022-131370 discloses a configuration in which a groove is formed in a region between lead terminals adjacent to each other on a lower surface of a semiconductor package to secure a creepage distance between the lead terminals.

The bottom surface of the semiconductor module is used as a heat dissipation surface. For example, a configuration is assumed in which the heat dissipation surface of the semiconductor module faces a cooler (for example, a heat sink) via a thermally conductive material such as thermally conductive grease. However, in a configuration in which the groove for securing the creepage distance is formed on the bottom surface of the semiconductor module, the thermally conductive material enters the groove, and as a result, the thermally conductive material interposed between the semiconductor module and the cooler may be insufficient.

### SUMMARY

In view of the above circumstances, an object of one aspect of the present disclosure is to ensure a creepage distance between a connection terminal and a heat dissipation surface while suppressing shortage of a thermally conductive material installed on the heat dissipation surface.

A semiconductor module according to one aspect of the present disclosure includes: an accommodating member having a first main surface and a second main surface that face opposite directions, and a side surface between the first main surface and the second main surface; a mounting substrate accommodated in the accommodating member; a semiconductor chip mounted to the mounting substrate; and a connection terminal protruding from the side surface, in which the second main surface includes a base surface in which an opening is formed, and a first stepped surface positioned between the base surface and the side surface in plan view and recessed toward the first main surface with respect to the base surface, the mounting substrate has a heat dissipation surface positioned inside the opening, and a first groove recessed toward the first main surface and extending in an extending direction of the side surface is formed in the first stepped surface.

A semiconductor module according to another aspect of the present disclosure includes: an accommodating member including a first main surface and a second main surface that face opposite directions, and a first side surface and a third side surface that face opposite directions between the first main surface and the second main surface; a mounting substrate accommodated in the accommodating member; a semiconductor chip mounted to the mounting substrate; a first connection terminal protruding from the first side surface; and a second connection terminal protruding from the third side surface, in which the second main surface includes: a base surface in which an opening is formed; a first stepped surface positioned between the base surface and the first side surface in plan view and recessed toward the first main surface with respect to the base surface; and a second stepped surface positioned between the base surface and the third side surface in plan view and recessed toward the first main surface with respect to the base surface, the mounting substrate has a heat dissipation surface positioned inside the opening, a first groove recessed toward the first main surface and extending in an extending direction of the first side surface is formed in the first stepped surface, and a second groove recessed toward the first main surface and extending in an extending direction of the third side surface is formed in the second stepped surface.

### BRIEF DESCRIPTION OF THE DRAWINGS

FIG. 1 is a cross-sectional view of a semiconductor module according to a first embodiment;

FIG. 2 is a plan view of the semiconductor module when viewed from a -Z direction;

FIG. 3 is an enlarged cross-sectional view of the vicinity of a second main surface in the semiconductor module;

FIG. 4 is a plan view of a semiconductor module of a second embodiment when viewed from the -Z direction;

FIG. 5 is a cross-sectional view of the vicinity of a second main surface in the semiconductor module of the second embodiment;

FIG. 6 is a cross-sectional view of the vicinity of a second main surface in a semiconductor module of a third embodiment;

FIG. 7 is a cross-sectional view of the vicinity of a second main surface in a semiconductor module of a fourth embodiment;

FIG. 8 is a cross-sectional view of the vicinity of a second main surface in a semiconductor module of a fifth embodiment;

FIG. 9 is a plan view of a semiconductor module of a sixth embodiment when viewed from the -Z direction;

FIG. 10 is a plan view of a semiconductor module of a seventh embodiment when viewed from the -Z direction;

FIG. 11 is a cross-sectional view of the vicinity of a second main surface in a semiconductor module of a modified example;

FIG. 12 is a cross-sectional view of the vicinity of a second main surface in a semiconductor module of a modified example;

FIG. 13 is a plan view of a semiconductor module of a modified example when viewed from the -Z direction; and

FIG. 14 is a plan view of a semiconductor module of a modified example when viewed from the -Z direction.

### DESCRIPTION OF THE EMBODIMENTS

Embodiments for carrying out the present disclosure will be described with reference to the drawings. In each drawing, dimensions and scales of each element may be different from those of an actual product. In addition, the embodiments described below are exemplary embodiments assumed in the case of implementing the present disclosure. Therefore, the scope of the present disclosure is not limited to the following exemplary embodiments.

### 1. First Embodiment

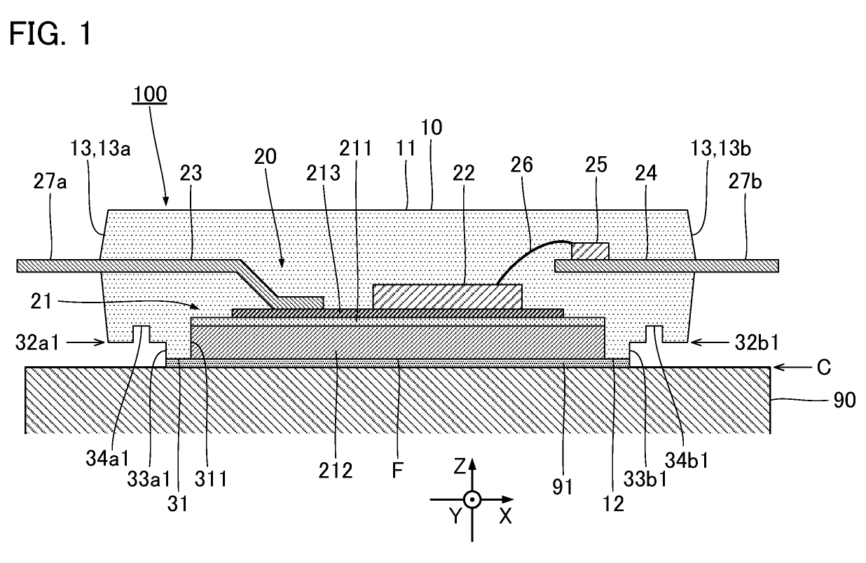

FIG. 1 is a cross-sectional view of a semiconductor module 100 according to a first embodiment of the present disclosure. The semiconductor module 100 of the first embodiment is a power semiconductor module used in a power conversion device such as an inverter circuit.

In the following description, three axes (X axis, Y axis, and Z axis) orthogonal to each other are assumed. A direction (+X direction and -X direction) along the X axis is referred to as an “X direction”. Similarly, a direction (+Y direction and -Y direction) along the Y axis is referred to as a “Y direction”, and a direction (+Z direction and -Z direction) along the Z axis is referred to as a “Z direction”.

In an actual use state, the semiconductor module 100 can be installed in any direction, but in the following description, the +Z direction is assumed to be an upper side and the -Z direction is assumed to be a lower side, for convenience. Therefore, a surface of any element of the semiconductor module 100 that faces the +Z direction may be referred to as an “upper surface”, and a surface of the element that faces the -Z direction may be referred to as a “lower surface”. In the following description, viewing any element of the semiconductor module 100 along a line of sight in the Z direction is referred to as “plan view”. Note that the directions (X direction, Y direction, and Z direction) of the three orthogonal axes and the direction of gravity are irrelevant.

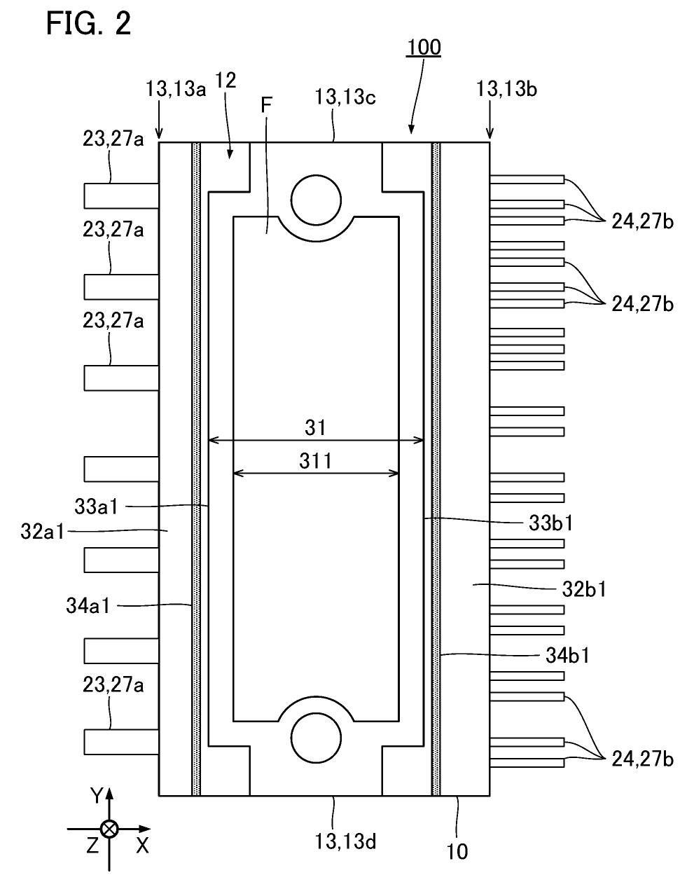

FIG. 2 is a plan view of the semiconductor module 100 when viewed from the -Z direction. That is, FIG. 2 illustrates a lower surface of the semiconductor module 100. As illustrated in FIGS. 1 and 2, the semiconductor module 100 of the first embodiment includes an accommodating member 10 and a semiconductor unit 20.

The accommodating member 10 is a structure that accommodates the semiconductor unit 20. The accommodating member 10 is formed of, for example, a thermoplastic resin or a thermosetting resin. Examples of the thermoplastic resin include a polyphenylene sulfide (PPS) resin, a polybutylene terephthalate (PBT) resin, a polybutylene succinate (PBS) resin, a polyamide (PA) resin, and an acrylonitrile-butadiene-styrene (ABS) resin. Examples of the thermosetting resin include an epoxy resin. For example, the accommodating member 10 and the semiconductor unit 20 are integrally formed by transfer molding in which a molding die in which the semiconductor unit 20 is installed is filled with a liquid resin material. As described above, the semiconductor module 100 of the first embodiment is a full-mold semiconductor package.

The accommodating member 10 is formed in a flat substantially rectangular parallelepiped shape having a first main surface 11 and a second main surface 12 facing opposite directions, and a side surface 13 between the first main surface 11 and the second main surface 12. The first main surface 11 is a substantially rectangular upper surface (top surface) of the accommodating member 10 that faces the +Z direction. The second main surface 12 is a substantially rectangular lower surface (bottom surface) of the accommodating member 10 that faces the -Z direction. The Z direction is a direction from one of the first main surface 11 and the second main surface 12 toward the other, and corresponds to a thickness direction (height direction) of the accommodating member 10.

The side surface 13 is an outer wall surface connecting the first main surface 11 and the second main surface 12. Specifically, the side surface 13 includes a side surface 13a, a side surface 13b, a side surface 13c, and a side surface 13d. The side surface 13a and the side surface 13b are outer wall surfaces facing opposite directions between the first main surface 11 and the second main surface 12. Specifically, the side surface 13a is a region facing the -X direction in the side surface 13 of the accommodating member 10. The side surface 13b is a region facing the +X direction in the side surface 13 of the accommodating member 10. That is, the Y direction is expressed as a direction in which the side surface 13a or the side surface 13b extends in plan view (hereinafter, referred to as an “extending direction”).

The side surface 13c and the side surface 13d are outer wall surfaces facing opposite directions between the first main surface 11 and the second main surface 12. Specifically, the side surface 13c is a region facing the +Y direction in the side surface 13 of the accommodating member 10. The side surface 13d is a surface facing the -Y direction in the side surface 13 of the accommodating member 10. That is, each of the side surface 13a and the side surface 13b and each of the side surface 13c and the side surface 13d intersect each other in plan view.

As illustrated in FIG. 1, the semiconductor unit 20 includes a mounting substrate 21, a semiconductor chip 22, a connection lead 23, a control lead 24, and a control chip 25. The mounting substrate 21 is a wiring substrate on which the semiconductor chip 22 is mounted. For example, a direct copper bonding (DCB) substrate, an active metal brazing (AMB) substrate, or an insulated metal substrate (IMS) substrate is used as the mounting substrate 21. The mounting substrate 21 is accommodated in the accommodating member 10.

The mounting substrate 21 is formed by stacking an insulating substrate 211, a heat dissipation plate 212, and a conductive pattern 213. The insulating substrate 211 is a rectangular plate-like member made of an insulating material. The insulating substrate 211 is formed of, for example, a ceramic material such as aluminum oxide, aluminum nitride, or silicon nitride, or a resin material such as an epoxy resin.

The heat dissipation plate 212 is a plate-like member bonded to a surface (that is, a lower surface) of the insulating substrate 211, the surface facing the -Z direction. The heat dissipation plate 212 is made of a metal material having high thermal conductivity, such as copper or aluminum. A surface of the heat dissipation plate 212 that faces the -Z direction (hereinafter, referred to as a “heat dissipation surface F”) faces a surface C of a cooler 90. The cooler 90 is, for example, a heat dissipation member such as a heat sink.

A thermally conductive material 91 is disposed between the heat dissipation surface F of the mounting substrate 21 and the surface C of the cooler 90. The thermally conductive material 91 is, for example, a fluid thermally conductive material such as thermally conductive grease. Heat propagating from the semiconductor chip 22 to the insulating substrate 211 propagates from the heat dissipation surface F to the cooler 90 via the thermally conductive material 91. That is, the heat dissipation surface F is a surface for dissipating heat of the semiconductor module 100. The heat dissipation plate 212 may be used as a ground body set to a ground potential.

The conductive pattern 213 is a thin-film or thin-plate conductor installed on a surface (that is, an upper surface) of the insulating substrate 211 that faces the +Z direction. For example, the conductive pattern 213 is formed of a low-resistance conductive material such as copper or a copper alloy.

The semiconductor chip 22 is a power semiconductor element installed on the mounting substrate 21, and is used as a switching element that switches conduction and interruption of a current. The semiconductor chip 22 of the first embodiment is, for example, a reverse conducting insulated gate bipolar transistor (RC-IGBT) including an IGBT and a freewheeling diode (FWD). The semiconductor chip 22 is bonded to the conductive pattern 213 by a conductive bonding material (not illustrated) such as a solder or a sintered material. The semiconductor chip 22 is accommodated in the accommodating member 10. Although a plurality of semiconductor chips 22 is actually installed on the mounting substrate 21, only one semiconductor chip 22 is illustrated in FIG. 2 for convenience.

The connection lead 23 is a lead frame electrically connected to the semiconductor chip 22. As illustrated in FIG. 2, the semiconductor module 100 includes a plurality of connection leads 23 spaced from each other. Each connection lead 23 penetrates through the side surface 13a from the inside of the accommodating member 10 and is exposed to an external space. A portion of each connection lead 23 that is positioned inside the accommodating member 10 is electrically connected to a main electrode (for example, a collector electrode or an emitter electrode) of the semiconductor chip 22.

A portion of each connection lead 23 that is exposed to the external space (hereinafter, referred to as a “connection terminal 27a”) protrudes in the -X direction from the side surface 13a of the accommodating member 10. That is, a plurality of connection terminals 27a protruding outward (in the -X direction) from the side surface 13a is arranged at intervals in the Y direction on the side surface 13a of the accommodating member 10. Each connection terminal 27a is a conductor for electrically connecting the semiconductor unit 20 to an external device such as a power supply device or a load device. Specifically, the plurality of connection terminals 27a includes a power supply terminal (P terminal) for a high-side power supply voltage, a power supply terminal (N terminal) for a low-side power supply voltage, and output terminals (U terminal, V terminal, and W terminal) for supplying power to the load device such as an electric motor.

The control lead 24 is a lead frame used to control the semiconductor module 100. As illustrated in FIG. 2, the semiconductor module 100 includes a plurality of control leads 24 spaced from each other. Each control lead 24 penetrates through the side surface 13b from the inside of the accommodating member 10 and is exposed to the external space. The control chip 25 is mounted at a portion of each control lead 24 that is positioned inside the accommodating member 10. The control chip 25 is accommodated in the accommodating member 10.

The control chip 25 is a drive circuit that controls the semiconductor chip 22. The control chip 25 is electrically connected to the semiconductor chip 22 by, for example, a wire 26. As described above, the semiconductor module 100 of the first embodiment is an intelligent power module (IPM) with the built-in control chip 25. However, the control chip 25 may be omitted from the semiconductor module 100.

A portion of each control lead 24 that is exposed to the external space (hereinafter, referred to as a “connection terminal 27b”) protrudes in the +X direction from the side surface 13b of the accommodating member 10. That is, a plurality of connection terminals 27b protruding outward (+X direction) from the side surface 13b is arranged at intervals in the Y direction on the side surface 13b of the accommodating member 10. Each connection terminal 27b is a conductor for electrically connecting the semiconductor unit 20 to an external device.

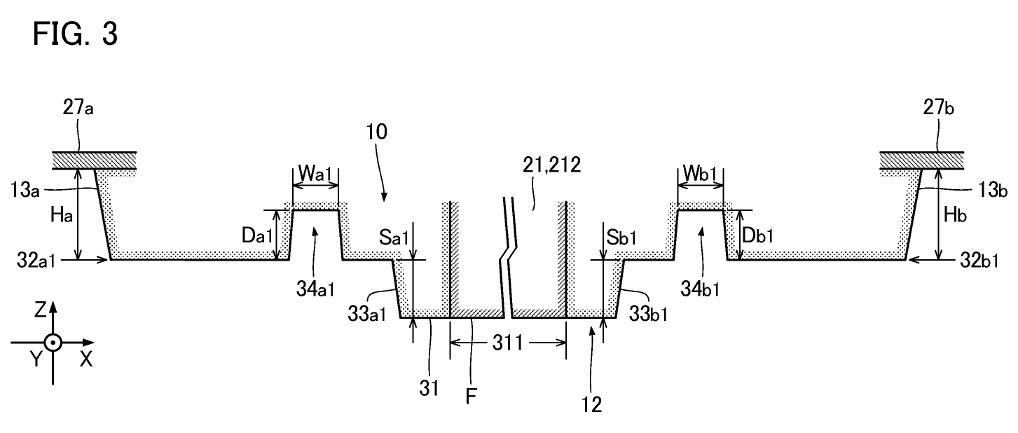

FIG. 3 is an enlarged cross-sectional view of the vicinity of the second main surface 12 of the accommodating member 10. As illustrated in FIGS. 2 and 3, the second main surface 12 of the accommodating member 10 includes a base surface 31, a stepped surface 32a1, a connection surface 33a1, a stepped surface 32b1, and a connection surface 33b1. The base surface 31 is positioned between the stepped surface 32a1 and the stepped surface 32b1 in plan view.

The base surface 31 is a horizontal flat surface along an X-Y plane in the second main surface 12. An opening 311 is formed in the base surface 31. The mounting substrate 21 is installed inside the opening 311 in plan view. That is, an inner wall surface of the opening 311 in the accommodating member 10 and an outer wall surface of the mounting substrate 21 are in close contact with each other. Accordingly, the heat dissipation surface F of the mounting substrate 21 is exposed to the inside of the opening 311. That is, the base surface 31 is a frame-shaped flat surface surrounding the entire periphery of the heat dissipation surface F. As illustrated in FIG. 1, the base surface 31 of the accommodating member 10 and the heat dissipation surface F of the mounting substrate 21 are positioned in the same plane, and the heat dissipation surface F of the mounting substrate 21 is exposed from the base surface 31.

As illustrated in FIG. 2, the stepped surface 32a1 is a region of the second main surface 12 that is positioned between the base surface 31 and the side surface 13a in plan view. The stepped surface 32a1 is a horizontal flat surface along the X-Y plane in the second main surface 12, and extends in the Y direction over the entire length of the accommodating member 10 in the Y direction. As illustrated in FIGS. 1 and 3, the stepped surface 32a1 is a surface recessed toward the first main surface 11 (+Z direction) with respect to the base surface 31. That is, the stepped surface 32a1 is positioned between the first main surface 11 and the second main surface 12 in the Z direction. In other words, the stepped surface 32a1 is positioned closer to the first main surface 11 than the base surface 31 is in the Z direction. Therefore, as illustrated in FIG. 1, the stepped surface 32a1 faces the surface C of the cooler 90 with a spacing therebetween.

The connection surface 33a1 is a wall surface connecting the base surface 31 and the stepped surface 32a1. That is, the connection surface 33a1 intersects the base surface 31 and the stepped surface 32a1. As illustrated in FIG. 3, a height difference Sa1 between the base surface 31 and the stepped surface 32a1 corresponds to a height of the connection surface 33a1. The height difference Sa1 is, for example, 1 mm or greater. Accordingly, a spacing of at least 1 mm is secured between the stepped surface 32a1 and the surface C of the cooler 90. However, the numerical value of the height difference Sa1 is not limited to the above range and may be modified as appropriate.

A groove 34a1 is formed in the stepped surface 32a1. The groove 34a1 is a recess recessed toward the first main surface 11 with respect to the stepped surface 32a1. Specifically, as illustrated in FIG. 2, the groove 34a1 extends linearly in the extending direction (Y direction) of the side surface 13a in plan view. The groove 34a1 of the first embodiment extends in the Y direction over the entire length of the accommodating member 10 (or the stepped surface 32a1) in the Y direction. The groove 34a1 is formed at a position spaced from the connection surface 33a1 in the -X direction.

As illustrated in FIG. 3, a cross-sectional shape of the groove 34a1 is a rectangular shape (for example, an oblong shape or a trapezoidal shape). A depth Da1 of the groove 34a1 is less than a distance Ha between a lower surface of the connection terminal 27a and the stepped surface 32a1. The depth Da1 is a distance between a bottom surface of the groove 34a1 and the stepped surface 32a1. The depth Da1 of the groove 34a1 is, for example, equal to or less than half of the distance Ha between the lower surface of the connection terminal 27a and the stepped surface 32a1. The depth Da1 of the groove 34a1 is equal to the height difference Sa1 between the base surface 31 and the stepped surface 32a1. A width Wa1 of the groove 34a1 is, for example, 0.5 mm or more. The width Wa1 is a dimension of the bottom surface of the groove 34a1 in the X direction.

As illustrated in FIG. 2, the stepped surface 32b1 is a region of the second main surface 12 that is positioned between the base surface 31 and the side surface 13b in plan view. The stepped surface 32b1 is a horizontal flat surface along the X-Y plane in the second main surface 12, and extends in the Y direction over the entire length of the accommodating member 10 in the Y direction. As illustrated in FIGS. 1 and 3, the stepped surface 32b1 is a surface recessed toward the first main surface 11 (+Z direction) with respect to the base surface 31. That is, the stepped surface 32b1 is positioned between the first main surface 11 and the second main surface 12 in the Z direction. In other words, the stepped surface 32b1 is positioned closer to the first main surface 11 than the base surface 31 is in the Z direction. Therefore, as illustrated in FIG. 1, the stepped surface 32b1 faces the surface C of the cooler 90 with a spacing therebetween.

The connection surface 33b1 is a wall surface connecting the base surface 31 and the stepped surface 32b1. That is, the connection surface 33b1 intersects the base surface 31 and the stepped surface 32b1. As illustrated in FIG. 3, a height difference Sb1 between the base surface 31 and the stepped surface 32b1 corresponds to a height of the connection surface 33b1. The height difference Sb1 is, for example, 1 mm or greater. Accordingly, a spacing of at least 1 mm is secured between the stepped surface 32b1 and the surface C of the cooler 90. However, the numerical value of the height difference Sb1 is not limited to the above range and may be modified as appropriate.

A groove 34b1 is formed in the stepped surface 32b1. The groove 34b1 is a recess recessed toward the first main surface 11 with respect to the stepped surface 32b1. Specifically, as illustrated in FIG. 2, the groove 34b1 linearly extends in the extending direction (Y direction) of the side surface 13b in plan view. The groove 34b1 of the first embodiment extends in the Y direction over the entire length of the accommodating member 10 (or the stepped surface 32b1) in the Y direction. The groove 34b1 is formed at a position spaced from the connection surface 33b1 in the +X direction.

As illustrated in FIG. 3, a cross-sectional shape of the groove 34b1 is a rectangular shape (for example, an oblong shape or a trapezoidal shape). A depth Db1 of the groove 34b1 is less than a distance Hb between a lower surface of the connection terminal 27b and the stepped surface 32b1. The depth Db1 is a distance between a bottom surface of the groove 34b1 and the stepped surface 32b1. The depth Db1 of the groove 34b1 is equal to the height difference Sb1 between the base surface 31 and the stepped surface 32b1. A width Wb1 of the groove 34b1 is, for example, 0.5 mm or more. The width Wb1 is a dimension of the bottom surface of the groove 34b1 in the X direction.

As described above, in the first embodiment, the groove 34a1 extending in an extending direction (Y direction) of the side surface 13a of the accommodating member 10 is formed in the second main surface 12 (stepped surface 32a1). Therefore, it is easy to secure a creepage distance between the connection terminal 27a and the heat dissipation surface F. Similarly, the groove 34b1 extending in the extending direction (Y direction) of the side surface 13b of the accommodating member 10 is formed in the second main surface 12 (stepped surface 32b1). Therefore, it is easy to secure a creepage distance between the connection terminal 27b and the heat dissipation surface F. In other words, it is possible to reduce a height of the accommodating member 10 (a distance between the first main surface 11 and the base surface 31) necessary for securing a sufficient creepage distance between the connection terminal 27a or 27b and the heat dissipation surface F. In the first embodiment, in particular, the groove 34a1 and the groove 34b1 are formed in the second main surface 12. Therefore, as compared with a configuration in which only one of the groove 34a1 and the groove 34b1 is formed, there is an advantage in that it is easy to secure the creepage distance between both the connection terminal 27a and the connection terminal 27b and the heat dissipation surface F.

In the first embodiment, the groove 34a1 is formed in the stepped surface 32a1 recessed toward the first main surface 11 with respect to the base surface 31 in the second main surface 12 of the accommodating member 10. Therefore, the probability that the thermally conductive material 91 will enter the groove 34a1 can be reduced as compared with a configuration in which the groove 34a1 is formed in the base surface 31. Similarly, the groove 34b1 is formed in the stepped surface 32b1 recessed toward the first main surface 11 with respect to the base surface 31 in the second main surface 12 of the accommodating member 10. Therefore, it is possible to reduce the likelihood that the thermally conductive material 91 will enter into the groove 34b1 as compared with a configuration in which the groove 34b1 is formed in the base surface 31. As a result of the reduced penetration of the thermally conductive material 91 into the groove 34a1 or the groove 34b1, the thermally conductive material 91 uniformly spreads between the base surface 31 and the cooler 90. Accordingly, shortage of the thermally conductive material 91 between the base surface 31 and the cooler 90 can be suppressed.

Furthermore, the depth Da1 of the groove 34a1 is preferably equal to or less than half of the distance Ha between the lower surface of the connection terminal 27a and the stepped surface 32a1. When the depth Da1 of the groove 34a1 becomes greater than half of the distance Ha, the connection terminal 27a and the bottom surface of the groove 34a1 become close to each other, as a result of which a mechanical strength of the accommodating member 10 decreases. With a configuration in which the depth Da1 of the groove 34a1 is equal to or less than half of the distance Ha, the mechanical strength of the accommodating member 10 can be maintained.

In the first embodiment, in particular, the groove 34a1 is continuous over the entire length of the accommodating member 10 in the extending direction of the side surface 13a. Therefore, it is easy to secure the creepage distance between the plurality of connection terminals 27a and the heat dissipation surface F over the entire length of the accommodating member 10 in the Y direction. Similarly, since the groove 34b1 is continuous over the entire length of the accommodating member 10 in the extending direction of the side surface 13b, it is easy to secure the creepage distance between the plurality of connection terminals 27b and the heat dissipation surface F over the entire length of the accommodating member 10 in the Y direction.

Furthermore, in the first embodiment, the height difference Sa1 between the base surface 31 and the stepped surface 32a1 is 1 mm or greater. That is, a spacing of at least 1 mm is secured between the stepped surface 32a1 and the surface C of the cooler 90. Accordingly, a creepage distance can be secured between the connection terminal 27a and the surface C of the cooler 90. Likewise, in the first embodiment, since the height difference Sb1 between the base surface 31 and the stepped surface 32b1 is 1 mm or greater, a creepage distance can be effectively secured between the connection terminal 27b and the surface C of the cooler 90.

### 2. Second Embodiment

A second embodiment will now be described. Note that elements having the same functions as those of the first embodiment in the respective aspects exemplified below are denoted by the same reference numerals as those in the description of the first embodiment, and detailed description thereof will be appropriately omitted.

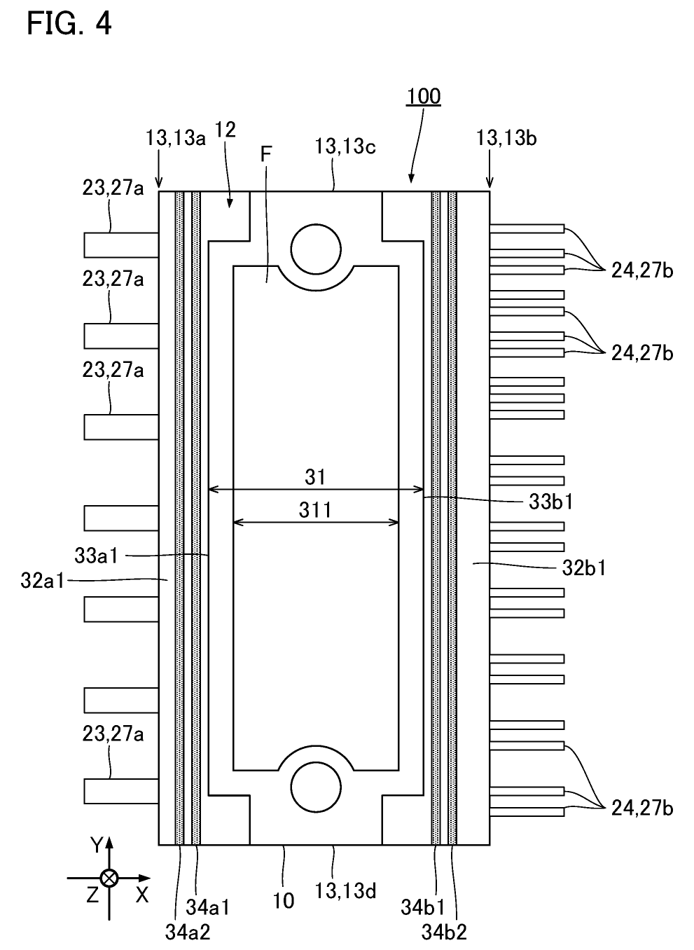

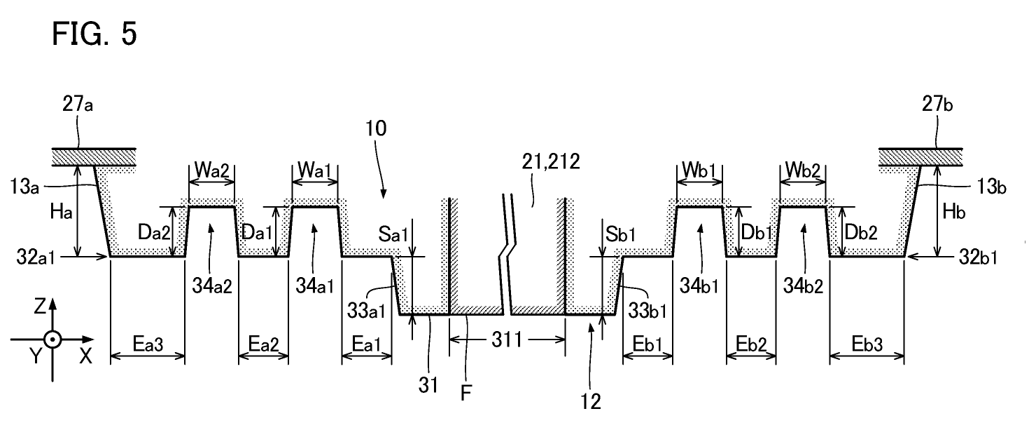

FIG. 4 is a plan view of a semiconductor module 100 of the second embodiment when viewed from a -Z direction. FIG. 5 is an enlarged cross-sectional view of the vicinity of a second main surface 12 in the semiconductor module 100. Similarly to the first embodiment, the second main surface 12 of the second embodiment includes a base surface 31, a stepped surface 32a1, a connection surface 33a1, a stepped surface 32b1, and a connection surface 33b1.

As illustrated in FIGS. 4 and 5, in addition to a groove 34a1 similar to that in the first embodiment, a groove 34a2 parallel to the groove 34a1 is formed in the stepped surface 32a1. That is, the groove 34a1 and the groove 34a2 are disposed adjacent to each other with a spacing therebetween in the X direction. The groove 34a2 is a recess formed between a side surface 13a and the groove 34a1 of the stepped surface 32a1 and recessed toward a first main surface 11. Similarly to the groove 34a1, the groove 34a2 linearly extends in an extending direction (Y direction) of the side surface 13a. Specifically, the groove 34a2 extends in the Y direction over the entire length of an accommodating member 10 (or the stepped surface 32a1) in the Y direction.

A cross-sectional shape of the groove 34a2 is a rectangular shape (for example, an oblong shape or a trapezoidal shape) similar to that of the groove 34a1. A depth Da2 of the groove 34a2 is the same as a depth Da1 of the groove 34a1. Therefore, the depth Da2 is less than a distance Ha between a lower surface of a connection terminal 27a and the stepped surface 32a1. A width Wa2 of the groove 34a2 is equal to a width Wa1 of the groove 34a1. That is, the width Wa2 of the groove 34a2 is, for example, 0.5 mm or more.

An interval Ea1 between the connection surface 33a1 and the groove 34a1 is, for example, 0.5 mm or more. Similarly, an interval Ea2 between the groove 34a1 and the groove 34a2 is, for example, 0.5 mm or more. Similarly, an interval Ea3 between the side surface 13a and the groove 34a2 is, for example, 0.5 mm or more.

As illustrated in FIGS. 4 and 5, in addition to a groove 34b1 similar to that in the first embodiment, a groove 34b2 parallel to the groove 34b1 is formed in the stepped surface 32b1. That is, the groove 34b1 and the groove 34b2 are disposed adjacent to each other with a spacing therebetween in the X direction. The groove 34b2 is a recess formed between a side surface 13b and the groove 34b1 of the stepped surface 32b1 and recessed toward the first main surface 11. Similarly to the groove 34b1, the groove 34b2 linearly extends in an extending direction (Y direction) of the side surface 13b. Specifically, the groove 34b2 extends in the Y direction over the entire length of the accommodating member 10 (or the stepped surface 32b1) in the Y direction.

A cross-sectional shape of the groove 34b2 is a rectangular shape (for example, an oblong shape or a trapezoidal shape) similar to that of the groove 34b1. A depth Db2 of the groove 34b2 is the same as a depth Db1 of the groove 34b1. Therefore, the depth Db2 is less than a distance Hb between a lower surface of a connection terminal 27b and the stepped surface 32b1. A width Wb2 of the groove 34b2 is equal to a width Wb1 of the groove 34b1. That is, the width Wb2 of the groove 34b2 is, for example, 0.5 mm or more.

An interval Eb1 between the connection surface 33b1 and the groove 34b1 is, for example, 0.5 mm or more. Similarly, an interval Eb2 between the groove 34b1 and the groove 34b2 is, for example, 0.5 mm or more. Similarly, an interval Eb3 between the side surface 13b and the groove 34b2 is, for example, 0.5 mm or more.

Also in the second embodiment, effects similar to those of the first embodiment are obtained. In the second embodiment, the groove 34a1 and the groove 34a2 are formed in the stepped surface 32a1 of the accommodating member 10. Therefore, it is easier to secure a creepage distance between the connection terminal 27a and a heat dissipation surface F as compared with a configuration in which only the groove 34a1 is formed in the stepped surface 32a1 (for example, the first embodiment). Similarly, since the groove 34b1 and the groove 34b2 are formed in the stepped surface 32b1 of the accommodating member 10, it is easier to secure a creepage distance between the connection terminal 27b and the heat dissipation surface F. In addition, since the creepage distances between the connection terminal 27a and the connection terminal 27b and the heat dissipation surface F can be secured more reliably, a height of the accommodating member 10 (a distance between the first main surface 11 and the base surface 31) required for securing a sufficient creepage distance between the connection terminal 27a or 27b and the heat dissipation surface F is reduced, so that the height of the semiconductor module 100 can be reduced.

### 3. Third Embodiment

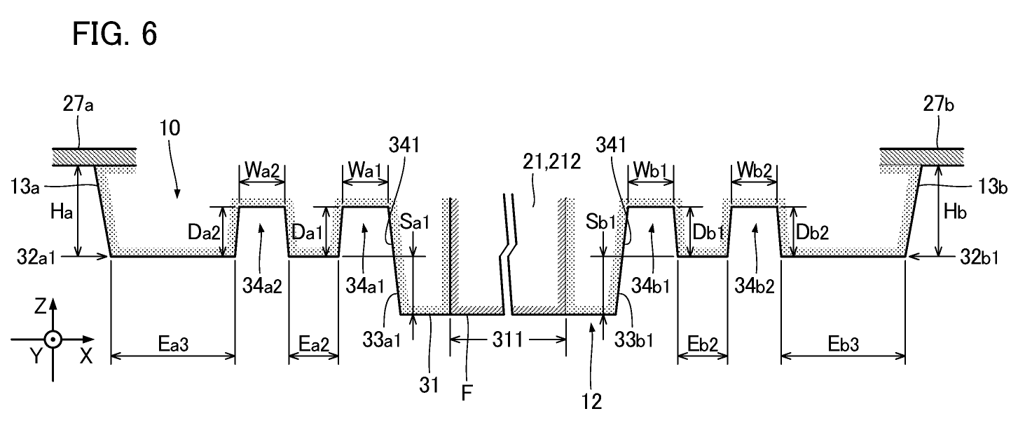

FIG. 6 is an enlarged cross-sectional view of the vicinity of a second main surface 12 in a semiconductor module 100 of a third embodiment. Similarly to the first embodiment, the second main surface 12 of the third embodiment includes a base surface 31, a stepped surface 32a1, a connection surface 33a1, a stepped surface 32b1, and a connection surface 33b1. a

In the third embodiment, similarly to the second embodiment, a groove 34a1 and a groove 34a2 parallel to each other are formed in the stepped surface 32a1. In the second embodiment, the groove 34a1 is formed at a position spaced from the connection surface 33a1. In the third embodiment, the groove 34a1 is formed continuously with the connection surface 33a1. That is, an inner wall surface 341 of the groove 34a1 is continuous with the connection surface 33a1 between the base surface 31 and the stepped surface 32a1. In other words, in the third embodiment, an interval Ea1 between the connection surface 33a1 and the groove 34a1 is 0.

Similarly, in the third embodiment, the groove 34b1 is formed continuously with the connection surface 33b1. That is, an inner wall surface 341 of the groove 34b1 is continuous with the connection surface 33b1 between the base surface 31 and the stepped surface 32b1. In other words, in the third embodiment, an interval Eb1 between the connection surface 33b1 and the groove 34b1 is 0.

Also, in the third embodiment, effects similar to those of the second embodiment are obtained. In the third embodiment, the inner wall surface 341 of the groove 34a1 is continuous with the connection surface 33a1, and the inner wall surface 341 of the groove 34b1 is continuous with the connection surface 33b1. Therefore, a change in shape of the second main surface 12 of the accommodating member 10 is suppressed as compared with a configuration (second embodiment) in which the groove 34a1 is spaced from the connection surface 33a1 and the groove 34b1 is spaced from the connection surface 33b1. Therefore, concentration of stress on the second main surface 12 of the accommodating member 10 can be suppressed. Furthermore, according to the third embodiment, a length of the stepped surface 32a1 from the connection surface 33a1 to the side surface 13a and a length of the stepped surface 32b1 from the connection surface 33b1 to the side surface 13b can be reduced as compared with a configuration (second embodiment) in which the groove 34a1 is spaced from the connection surface 33a1 and the groove 34b1 is spaced from the connection surface 33b1. Therefore, the semiconductor module 100 can be reduced in size.

On the other hand, in the second embodiment, the groove 34a1 is formed to be spaced from the connection surface 33a1. Therefore, it is easier to secure a creepage distance between a connection terminal 27a and a heat dissipation surface F as compared with a configuration (third embodiment) in which the groove 34a1 is continuous with the connection surface 33a1. Similarly, in the second embodiment, since the groove 34b1 is formed to be spaced from the connection surface 33b1, it is easier to secure a creepage distance between a connection terminal 27b and the heat dissipation surface F. In other words, it is possible to reduce a height of the accommodating member 10 (a distance between a first main surface 11 and the base surface 31) necessary for securing a sufficient creepage distance between the connection terminal 27a or 27b and the heat dissipation surface F.

### 4. Fourth Embodiment

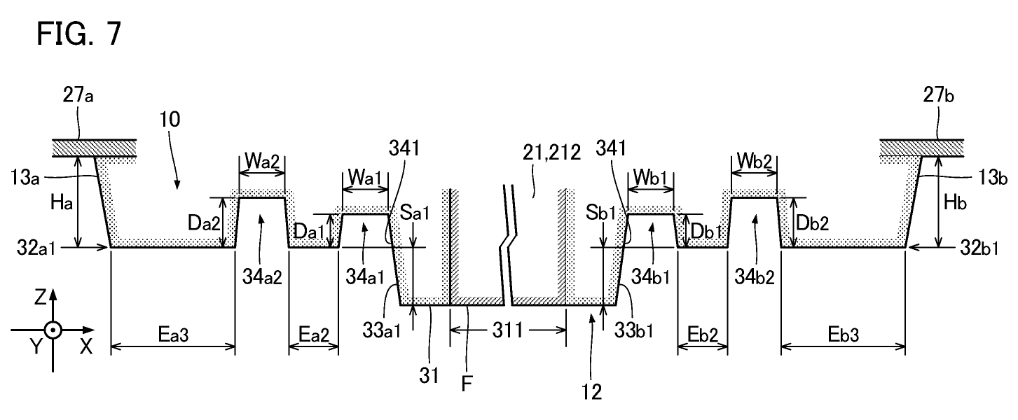

FIG. 7 is an enlarged cross-sectional view of the vicinity of a second main surface 12 in a semiconductor module 100 of a fourth embodiment. Similarly to the first embodiment, the second main surface 12 of the fourth embodiment includes a base surface 31, a stepped surface 32a1, a connection surface 33a1, a stepped surface 32b1, and a connection surface 33b1.

In the fourth embodiment, similarly to the third embodiment, a groove 34a1 and a groove 34a2 parallel to each other are formed in the stepped surface 32a1. As illustrated in FIG. 7, in the fourth embodiment, a depth Da1 of the groove 34a1 is different from a depth Da2 of the groove 34a2. Specifically, the depth Da1 of the groove 34a1 is less than the depth Da2 of the groove 34a2. On the other hand, a width Wa1 of the groove 34a1 and a width Wa2 of the groove 34a2 are the same as each other. Note that a configuration in which the depth Da1 of the groove 34a1 exceeds the depth Da2 of the groove 34a2 or a configuration in which the width Wa1 of the groove 34a1 is different from the width Wa2 of the groove 34a2 is also assumed.

Similarly, in the fourth embodiment, a depth Db1 of the groove 34b1 is different from a depth Db2 of the groove 34b2. Specifically, the depth Db1 of the groove 34b1 is less than the depth Db2 of the groove 34b2. On the other hand, a width Wb1 of the groove 34b1 and a width Wb2 of the groove 34b2 are the same as each other. A configuration in which the depth Db1 of the groove 34b1 exceeds the depth Db2 of the groove 34b2 or a configuration in which the width Wb1 of the groove 34b1 is different from the width Wb2 of the groove 34b2 is also assumed.

Also in the fourth embodiment, effects similar to those of the third embodiment are obtained. In a configuration in which both the groove 34a1 and the groove 34a2 are excessively deep, there is a possibility that a mechanical strength of an accommodating member 10 cannot be sufficiently secured. In the fourth embodiment, the depth Da1 of the groove 34a1 is different from the depth Da2 of the groove 34a2. Specifically, the depth Da1 of the groove 34a1 is less than the depth Da2 of the groove 34a2. Therefore, it is easier to secure the mechanical strength of the accommodating member 10 as compared with a configuration (third embodiment) in which the groove 34a1 and the groove 34a2 are restricted to the same depth. Similarly, in the fourth embodiment, since the depth Db1 of the groove 34b1 and the depth Db2 of the groove 34b2 are different from each other, it is easier to secure the mechanical strength of the accommodating member 10 as compared with a configuration (third embodiment) in which the groove 34b1 and the groove 34b2 are restricted to the same depth.

In the above description, a form in which the groove 34a1 is continuous with the connection surface 33a1 and the groove 34b1 is continuous with the connection surface 33b1 similarly to the third embodiment has been exemplified. However, a form in which the groove 34a1 is spaced from the connection surface 33a1 and the groove 34b1 is spaced from the connection surface 33b1 similarly to the second embodiment may also be applied to the fourth embodiment.

### 5. Fifth Embodiment

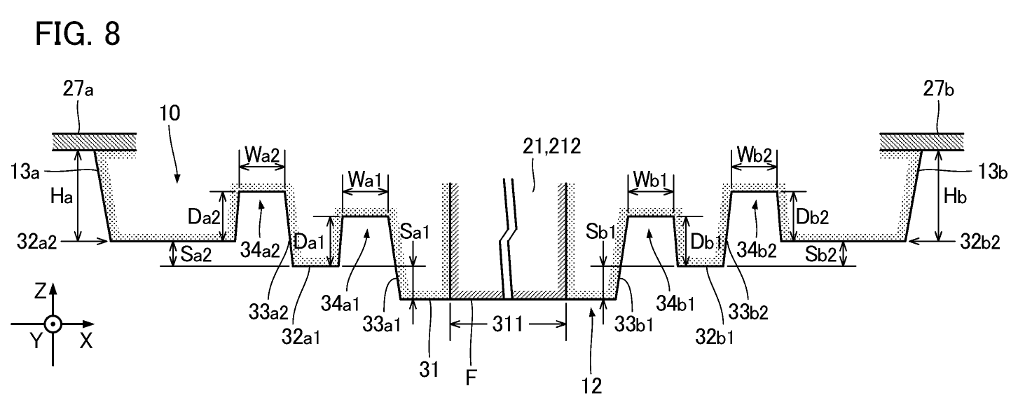

FIG. 8 is an enlarged cross-sectional view of the vicinity of a second main surface 12 in a semiconductor module 100 of a fifth embodiment. The second main surface 12 of the fifth embodiment includes a stepped surface 32a2, a connection surface 33a2, a stepped surface 32b2, and a connection surface 33b2 in addition to a base surface 31, a stepped surface 32a1, a connection surface 33a1, a stepped surface 32b1, and a connection surface 33b1. The stepped surface 32a1 and the stepped surface 32b1 are examples of a “first stepped surface”, and the stepped surface 32a2 and the stepped surface 32b2 are examples of a “second stepped surface”.

The stepped surface 32a2 is a region in the second main surface 12, the region being positioned between the stepped surface 32a1 and a side surface 13a in plan view. Similarly to the stepped surface 32a1, the stepped surface 32a2 is a horizontal flat surface along the X-Y plane in the second main surface 12, and extends in the Y direction over the entire length of an accommodating member 10 in the Y direction. The stepped surface 32a2 is a surface recessed toward a first main surface 11 (+Z direction) with respect to the stepped surface 32a1. That is, the stepped surface 32a2 is positioned between the first main surface 11 and the stepped surface 32a1 in the Z direction. In other words, the stepped surface 32a2 is positioned closer to the first main surface 11 than the stepped surface 32a1 is. Therefore, the stepped surface 32a2 faces a surface C of a cooler 90 with a spacing therebetween.

The connection surface 33a2 is a wall surface connecting the stepped surface 32a1 and the stepped surface 32a2. That is, the connection surface 33a2 intersects the stepped surface 32a1 and the stepped surface 32a2. A height difference Sa2 between the connection surface 33a1 and the connection surface 33a2 is less than a height difference Sa1 between the base surface 31 and the stepped surface 32a1.

In the second to fourth embodiments, a configuration in which both the groove 34a1 and the groove 34a2 are formed in the stepped surface 32a1 has been exemplified. In the fifth embodiment, the groove 34a1 is formed in the stepped surface 32a1, while the groove 34a2 is formed in the stepped surface 32a2. The groove 34a2 is a recess formed in the stepped surface 32a2 and recessed toward the first main surface 11. Specifically, the groove 34a2 extends linearly in an extending direction (Y direction) of the side surface 13a. Although FIG. 8 illustrates a configuration in which the groove 34a2 is continuous with the connection surface 33a2, the groove 34a2 may be spaced from the connection surface 33a2 in the -X direction.

The stepped surface 32b2 is a region in the second main surface 12, the region being positioned between the stepped surface 32b1 and the side surface 13b in plan view. Similarly to the stepped surface 32b1, the stepped surface 32b2 is a horizontal flat surface along the X-Y plane in the second main surface 12, and extends in the Y direction over the entire length of the accommodating member 10 in the Y direction. The stepped surface 32b2 is a surface recessed toward the first main surface 11 (+Z direction) with respect to the stepped surface 32b1. That is, the stepped surface 32b2 is positioned between the first main surface 11 and the stepped surface 32b1 in the Z direction. In other words, the stepped surface 32b2 is positioned closer to the first main surface 11 than the stepped surface 32b1 is. Therefore, the stepped surface 32b2 faces the surface C of the cooler 90 with a spacing therebetween.

The connection surface 33b2 is a wall surface connecting the stepped surface 32b1 and the stepped surface 32b2. That is, the connection surface 33b2 intersects the stepped surface 32b1 and the stepped surface 32b2. A height difference Sb2 between the connection surface 33b1 and the connection surface 33b2 is less than a height difference Sbb between the base surface 31 and the stepped surface 32b1.

In the second to fourth embodiments, a configuration in which both the groove 34b1 and the groove 34b2 are formed in the stepped surface 32b1 has been exemplified. In the fifth embodiment, the groove 34b1 is formed in the stepped surface 32b1, while the groove 34b2 is formed in the stepped surface 32b2. The groove 34b2 is a recess formed in the stepped surface 32b2 and recessed toward the first main surface 11. Specifically, the groove 34b2 linearly extends in an extending direction (Y direction) of a side surface 13b. Although FIG. 8 illustrates a configuration in which the groove 34b2 is continuous with the connection surface 33b2, the groove 34b2 may be spaced from the connection surface 33b2 in the +X direction.

Also in the fifth embodiment, effects similar to those of the third embodiment are obtained. In the fifth embodiment, the groove 34a1 is formed in the stepped surface 32a1, and the groove 34a2 is formed in the stepped surface 32a2 recessed toward the first main surface 11 with respect to the stepped surface 32a1. Therefore, it is easier to secure a creepage distance between a connection terminal 27a and a heat dissipation surface F as compared with a configuration in which only the groove 34a1 is formed (first embodiment) or a configuration in which both the groove 34a1 and the groove 34a2 are formed in the stepped surface 32a1 (second to fourth embodiments). Similarly, in the fifth embodiment, the groove 34b1 is formed in the stepped surface 32b1, and the groove 34b2 is formed in the stepped surface 32b2 recessed toward the first main surface 11 with respect to the stepped surface 32b1. Therefore, it is easy to secure a creepage distance between a connection terminal 27b and the heat dissipation surface F.

### 6. Sixth Embodiment

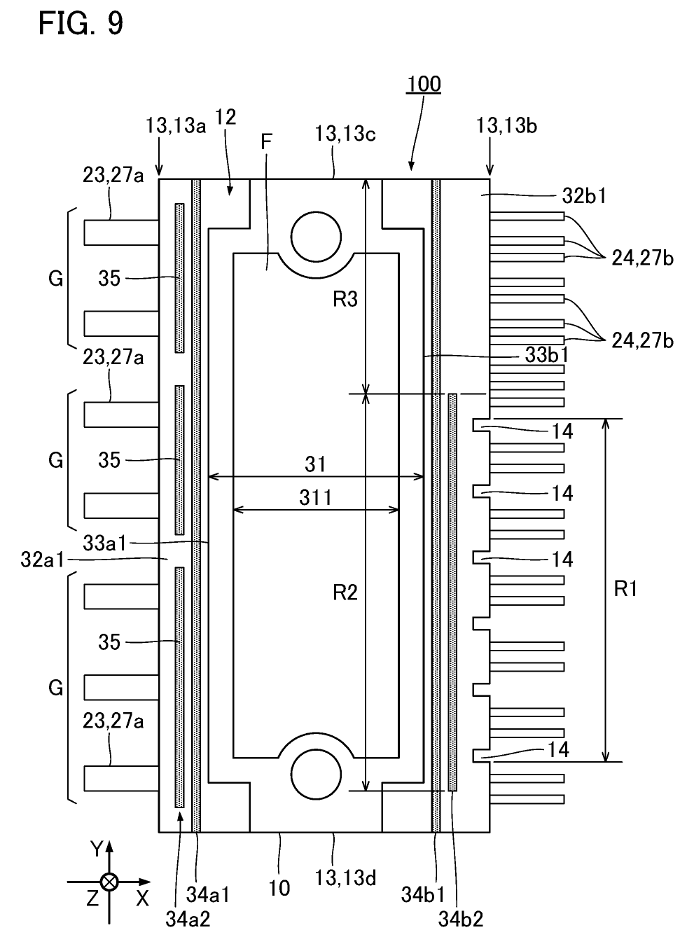

FIG. 9 is a plan view of a semiconductor module 100 of a sixth embodiment when viewed from the -Z direction. In the sixth embodiment, a groove 34a1 and a groove 34a2 are formed in a stepped surface 32a1 of a second main surface 12, and a groove 34b1 and a groove 34b2 are formed in the stepped surface 32b1, similarly to the second embodiment.

As illustrated in FIG. 9, the groove 34a2 formed in the stepped surface 32a1 includes a plurality of portions 35 arranged at intervals in an extending direction (Y direction) of a side surface 13a. That is, the groove 34a2 of the second embodiment is continuously formed along the Y axis, whereas the groove 34a2 of the sixth embodiment is intermittently formed along the Y axis.

Specifically, each portion 35 of the groove 34a2 is formed for each set (hereinafter, referred to as a “terminal group G”) of two or more connection terminals 27a adjacent to each other in the Y direction among a plurality of connection terminals 27a. A portion 35 that corresponds to any one terminal group G among the plurality of portions 35 extends in the Y direction over a range in which two or more connection terminals 27a included in the terminal group G are present. Therefore, an interval between two portions 35 adjacent to each other in the Y direction is positioned within an interval between two terminal groups G adjacent to each other in the Y direction.

As described above, in the sixth embodiment, the groove 34a2 includes the plurality of portions 35 arranged at intervals in the extending direction (Y direction) of the side surface 13a. That is, the groove 34a2 is not formed between two portions 35 adjacent to each other in the Y direction. Therefore, it is easier to secure a mechanical strength of an accommodating member 10 as compared with a configuration in which the groove 34a2 is continuous in the Y direction over the entire length of the accommodating member 10. The number of portions 35 of the groove 34a2 and the arrangement of the portions 35 are not particularly limited and may be freely changed as long as a creepage distance between the connection terminal 27a and a heat dissipation surface F is secured and the mechanical strength of the accommodating member 10 is secured. For example, each of the plurality of portions 35 may be formed for each connection terminal 27a.

In addition, a plurality of side surface grooves 14 is formed on a side surface 13b of the accommodating member 10 in the sixth embodiment. Each of the side surface grooves 14 is a recess extending in the Z direction on the side surface 13b. Specifically, the side surface groove 14 is formed between two connection terminals 27b adjacent to each other among a plurality of connection terminals 27b protruding from the side surface 13b. Specifically, the side surface groove 14 is formed between two connection terminals 27b having a large voltage difference among the plurality of connection terminals 27b. The above configuration has an advantage in that it is easier to secure a creepage distance between the connection terminals 27b adjacent to each other in the Y direction as compared with a configuration in which the side surface groove 14 is not formed. FIG. 9 illustrates a first range R1 in which the plurality of side surface grooves 14 is arranged in the Y direction.

The groove 34b2 formed in the stepped surface 32b1 of the sixth embodiment is continuous along the Y axis in a second range R2 corresponding to the first range R1 in which the plurality of side surface grooves 14 is arranged. The second range R2 is a range including the first range R1 in the Y direction, and is a partial range in the Y direction in the stepped surface 321. The groove 34b2 is not formed in a third range R3 outside the second range R2 in the stepped surface 32b1. On the other hand, the groove 34b1 ver the entire length of the stepped surface 32b1 in the Y direction as in each of the above-described embodiments. That is, the groove 34b1 is formed over both the second range R2 and the third range R3.

As described above, in the sixth embodiment, since the groove 34b2 is continuous in the second range R2 corresponding to the first range R1 in which the plurality of side surface grooves 14 is arranged in the accommodating member 10, there is an advantage in that it is easy to secure a creepage distance from the heat dissipation surface F for the connection terminal 27b in which securing the creepage distance by the side surface groove 14 is prioritized among the plurality of connection terminals 27b. In other words, it is possible to reduce a height of the accommodating member 10 (a distance between a first main surface 11 and a base surface 31) necessary for securing a sufficient creepage distance between the connection terminal 27b and the heat dissipation surface F.

In the above description, a configuration in which the groove 34b2 formed in the stepped surface 32b1 is formed within the second range R2 is exemplified, but a configuration in which the groove 34b1 of the stepped surface 32b1 is formed in the second range R2 or a configuration in which both the groove 34b1 and the groove 34b2 are formed in the second range R2 may also be adopted.

In addition, in the above description, a form in which the groove 34a2 includes the plurality of portions 35 has been exemplified, but a groove including the plurality of portions 35 is not limited to the groove 34a2. For example, a form in which the groove 34a1 is intermittently formed by the plurality of portions 35 and a form in which the groove 34b1 or the groove 34b2 includes the plurality of portions 35 are also assumed. In addition, a form in which the groove 34a1 is intermittently formed by the plurality of portions 35 in a configuration (first embodiment) in which only the groove 34a1 is provided in the stepped surface 32a1 and only the groove 34b1 is provided in the stepped surface 32b1 is also assumed.

### 7. Seventh Embodiment

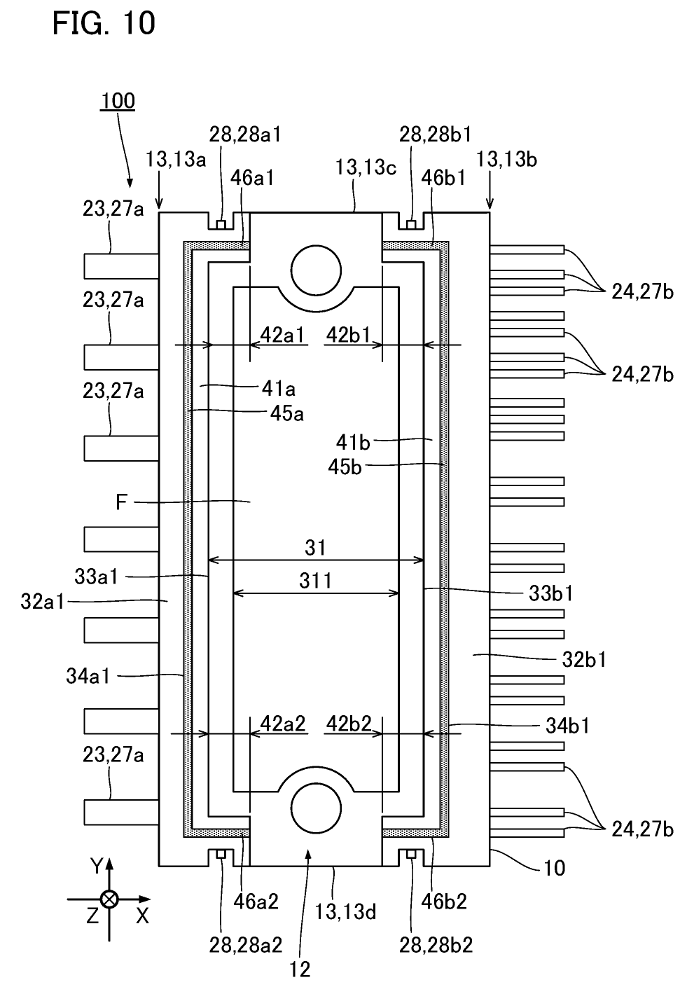

FIG. 10 is a plan view of a semiconductor module 100 of a seventh embodiment when viewed from the -Z direction. As illustrated in FIG. 10, the semiconductor module 100 of the seventh embodiment includes a plurality of auxiliary terminals 28 (28a1, 28a2, 28b1, and 28b2) in addition to the same elements as those of the first embodiment. Each auxiliary terminal 28 is an auxiliary terminal that does not directly contribute to an operation of the semiconductor module 100. For example, the auxiliary terminal 28 is a hanging terminal for holding a mounting substrate 21 in a manufacturing process of the semiconductor module 100. The auxiliary terminal 28 is electrically connected to, for example, a conductive pattern 213 set to a ground potential among a plurality of conductive patterns 213 of the mounting substrate 21 inside an accommodating member 10.

The auxiliary terminal 28a1 and the auxiliary terminal 28b1 are installed on a side surface 13c of the accommodating member 10. Specifically, the auxiliary terminal 28a1 is installed at a portion of a side surface 13c, the portion being close to a side surface 13a, and the auxiliary terminal 28b1 is installed at a portion of the side surface 13c, the portion being close to a side surface 13b. On the other hand, the auxiliary terminal 28a2 and the auxiliary terminal 28b2 are installed on a side surface 13d of the accommodating member 10. Specifically, the auxiliary terminal 28a2 is installed at a portion of the side surface 13d, the portion being close to the side surface 13a, and the auxiliary terminal 28b2 is installed at a portion of the side surface 13d, the portion being close to the side surface 13b.

A stepped surface 32a1 of the seventh embodiment includes an end portion region 42a1 and an end portion region 42a2 in addition to an extending region 41a linearly extending in the Y direction. The end portion region 42a1 is a region protruding in the +X direction from an end portion of the extending region 41ain the +Y direction in plan view. The end portion region 42a2 is a region protruding in the +X direction from an end portion of the extending region 41ain the -Y direction in plan view. Similarly, a stepped surface 32b1 includes an end portion region 42b1 and an end portion region 42b2 in addition to an extending region 41b extending linearly in the Y direction. The end portion region 42b1 is a region protruding in the -X direction from an end portion of the extending region 41bin the +Y direction in plan view. The end portion region 42b2 is a region protruding in the -X direction from an end portion of the extending region 41b in the -Y direction in plan view.

A groove 34a1 is formed in the stepped surface 32a1. The groove 34a1 of the seventh embodiment includes an extending portion 45a, an end portion 46a1, and an end portion 46a2. The extending portion 45a is a portion extending in an extending direction (Y direction) of the side surface 13a in the extending region 41a of the stepped surface 32a1. The end portion 46a1 and the end portion 46a2 are portions continuous with the extending portion 45a. The end portion 46a1 protrudes in the +X direction from an end portion of the extending portion 45ain the +Y direction. That is, the end portion 46a1 extends in the X direction along the side surface 13c in the end portion region 42a1. Therefore, the end portion 46a1 is positioned between the auxiliary terminal 28a1 and a base surface 31 in plan view. The end portion 46a2 protrudes in the +X direction from an end portion of the extending portion 45a in the -Y direction. That is, the end portion 46a2 extends in the X direction along the side surface 13d in the end portion region 42a2. Therefore, the end portion 46a2 is positioned between the auxiliary terminal 28a2 and the base surface 31 in plan view. The extending portion 45ais an example of a “first portion”, and the end portion 46a1 and the end portion 46a2 are examples of a “second portion”.

A groove 34b1 is formed in the stepped surface 32b1. The groove 34b1 of the seventh embodiment includes an extending portion 45b, an end portion 46b1, and an end portion 46b2. The extending portion 45b is a portion extending in an extending direction (Y direction) of the side surface 13b in the extending region 41b of the stepped surface 32b1. The end portion 46b1 and the end portion 46b2 are portions continuous with the extending portion 45b. The end portion 46b1 protrudes in the -X direction from an end portion of the extending portion 45b in the +Y direction. That is, the end portion 46b1 extends in the X direction along the side surface 13c in the end portion region 42b1. Therefore, the end portion 46b1 is positioned between the auxiliary terminal 28b1 and the base surface 31 in plan view. The end portion 46b2 protrudes in the -X direction from an end portion of the extending portion 45bin the -Y direction. That is, the end portion 46b2 extends in the X direction along the side surface 13d in the end portion region 42b2. Therefore, the end portion 46b2 is positioned between the auxiliary terminal 28b2 and the base surface 31 in plan view. The extending portion 45bis an example of the “first portion”, and the end portion 46b1 and the end portion 46b2 are examples of the “second portion”.

Also in the seventh embodiment, effects similar to those of the first embodiment are obtained. In the seventh embodiment, the groove 34b1 includes the extending portion 45a extending in the extending direction (Y direction) of the side surface 13a from which connection terminals 27a protrude, the end portion 46a1 extending along the side surface 13c from which the auxiliary terminal 28a1 protrudes, and the end portion 46a2 extending along the side surface 13d from which the auxiliary terminal 28a2 protrudes. Therefore, it is easy to secure a creepage distance between each of the auxiliary terminal 28a1 and the auxiliary terminal 28a2 and a heat dissipation surface F in addition to a creepage distance between each of the connection terminals 27a and the heat dissipation surface F. Similarly, in the seventh embodiment, since the groove 34b1 includes the extending portion 45b, the end portion 46b1, and the end portion 46b2, it is easy to secure a creepage distance between (i) each of the auxiliary terminal 28b1 and the auxiliary terminal 28b2 and (ii) the heat dissipation surface F. In other words, a height of the accommodating member 10 (a distance between a first main surface 11 and the base surface 31) necessary for securing a sufficient creepage distance between each auxiliary terminal 28 and the heat dissipation surface F can be reduced.

### 8. Modifications

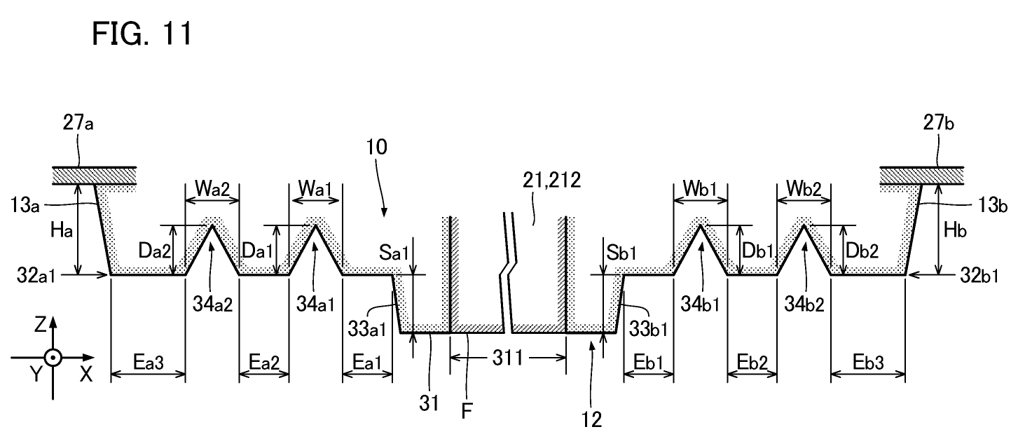

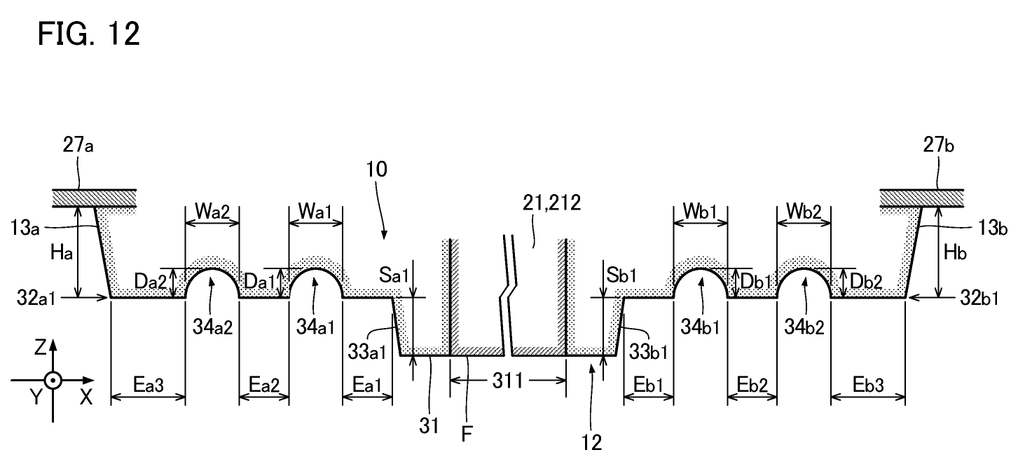

Specific modified aspects added to the embodiments exemplified above will be exemplified below. Two or more aspects freely selected from the following examples may be combined as appropriate as long as they do not conflict.
(1) The form (for example, a dimension or shape) of the groove 34 (34a1, 34a2, 34b1, and 34b2) formed in the second main surface 12 may be freely changed. For example, in each of the above-described embodiments, a configuration in which each groove 34 is formed linearly along the Y axis has been exemplified, but each groove 34 may be formed in, for example, a curved shape (for example, a wavy line shape) along the Y axis. In addition, the cross-sectional shape of each groove 34 is not limited to the rectangular shape exemplified in each of the above-described embodiments, and may be changed to any shape. For example, the cross-sectional shape of each groove 34 may be a triangular shape as illustrated in FIG. 11. Alternatively, the cross-sectional shape of each groove 34 may be a semicircular shape as illustrated in FIG. 12. As understood from the example of FIG. 12, an inner wall surface of the groove 34 does not need to be entirely flat, and may include a curved surface such as an arc surface, for example.
(2) In the first to fifth embodiments, a configuration in which the form (for example, the dimension or shape) of the groove 34 formed in the stepped surface 32a1 and the form of the groove 34 formed in the stepped surface 32b1 are the same has been exemplified, but the form of the groove 34 (34a1 and 34a2) in the stepped surface 32a1 and the form of the groove 34 (34b1 and 34b2) in the stepped surface 32b1 may be different from each other.

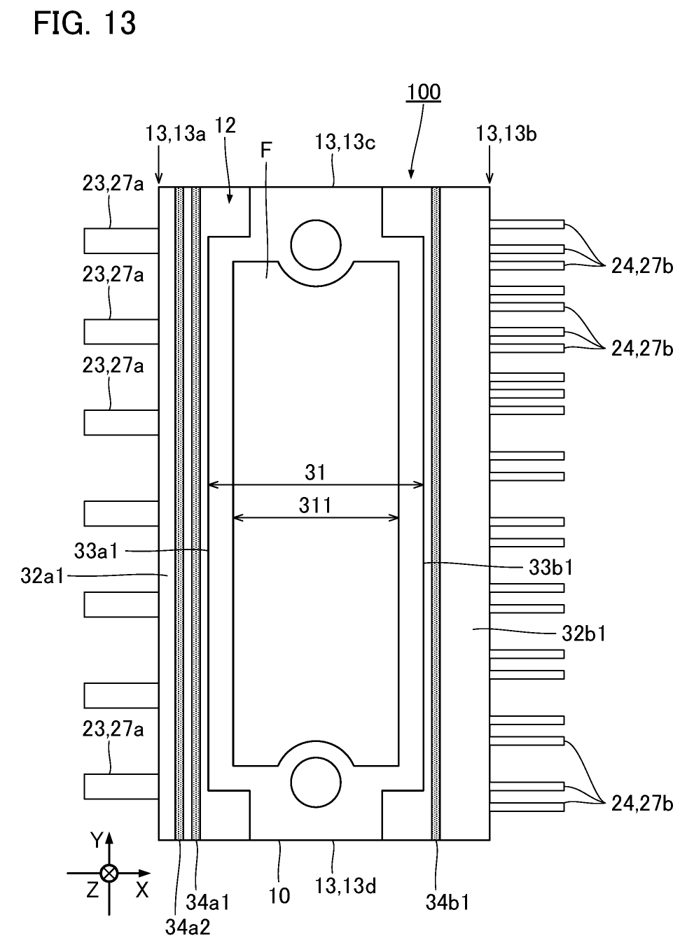

For example, the total number of grooves 34 formed in the stepped surface 32a1 may be different from the total number of grooves 34 formed in the stepped surface 32b1 as illustrated in FIG. 13. For example, a voltage difference between each connection lead 23 and the heat dissipation plate 212 sufficiently exceeds a voltage difference between each control lead 24 and the heat dissipation plate 212. Therefore, securing the creepage distance between each connection lead 23 and the heat dissipation surface F is prioritized over securing the creepage distance between each control lead 24 and the heat dissipation surface F. In consideration of the above circumstances, it is preferable that the total number of grooves 34 (two grooves 34a1 and 34a2) formed in the stepped surface 32a1 exceed the total number of grooves 34 (only one groove 34b1) formed in the stepped surface 32b1 as illustrated in FIG. 13. For the same reason, a configuration in which the depth Da1 of the groove 34a1 formed in the stepped surface 32a1 exceeds the depth Db1 of the groove 34b1 formed in the stepped surface 32b1 is also preferable.

(3) In each of the above-described embodiments, a configuration in which the grooves 34 (34a1, 34a2, 34b1, and 34b2) are formed in both the stepped surface 32a1 and the stepped surface 32b1 has been exemplified, but the groove 34 may be formed only in one of the stepped surface 32a1 and the stepped surface 32b1.

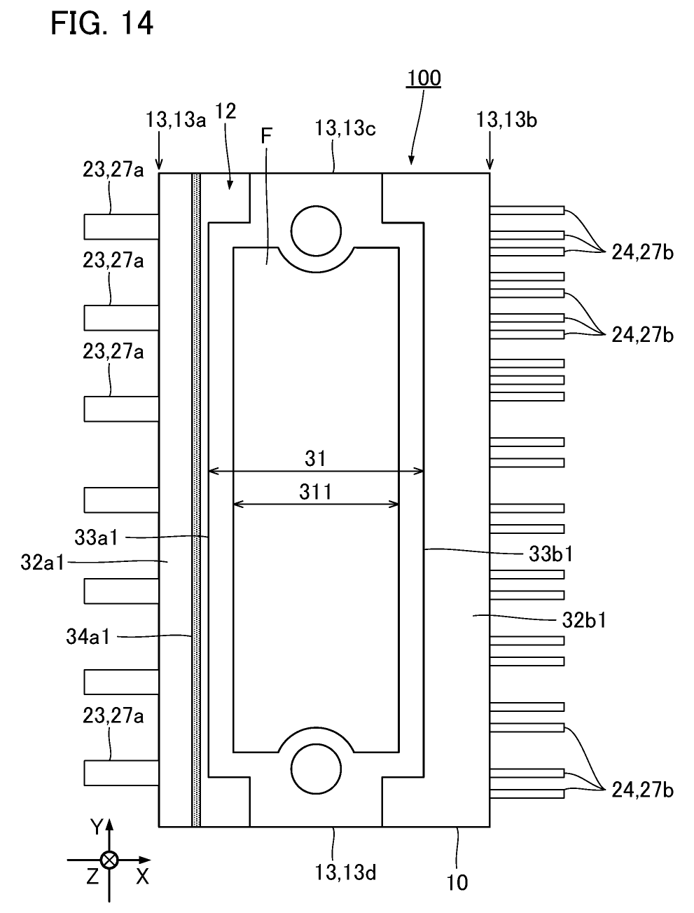

For example, in the embodiment illustrated in FIG. 14, the groove 34a1 similar to that of the first embodiment is formed in the stepped surface 32a1 corresponding to the side surface 13a of the accommodating member 10. The side surface 13a corresponding to the stepped surface 32a1 is the side surface 13 of the accommodating member 10 from which the connection terminal 27a of each connection lead 23 electrically connected to the main electrode of the semiconductor chip 22 protrudes. On the other hand, the stepped surface 32b1 corresponding to the side surface 13b is a flat surface in which the groove 34 is not formed. The side surface 13b corresponding to the stepped surface 32b1 is the side surface 13 from which the connection terminal 27a of each of the connection leads 23 electrically connected to the main electrode of the semiconductor chip 22 does not protrude.

A higher voltage than that of each connection terminal 27b is applied to each connection terminal 27a. Therefore, it is essential to secure a sufficient creepage distance between each connection terminal 27a and the heat dissipation surface F as compared with the connection terminal 27b. In the configuration of FIG. 14, since the groove 34a1 is formed in the stepped surface 32a1 close to each connection terminal 27a, it is easy to secure the creepage distance between each connection terminal 27a and the heat dissipation surface F. On the other hand, the stepped surface 32b1 positioned opposite to the plurality of connection terminals 27a is a flat surface in which no groove is formed. Therefore, there is an advantage in the mechanical strength of the stepped surface 32b1 being easily maintained. The configurations exemplified in the second to seventh embodiments and the modified examples are freely applied to the groove 34a1 in the form of FIG. 14.

(4) In each of the above-described embodiments, the full-mold semiconductor module 100 in which the accommodating member 10 and the semiconductor unit 20 are integrally formed by transfer molding has been exemplified, but the present disclosure is also applied to a semiconductor module having a structure in which the semiconductor unit 20 is accommodated in a rectangular frame-shaped resin case and the resin case is filled with a sealing material such as a resin material, similarly to each of the above-described embodiments. That is, the “accommodating member” in the present disclosure is broadly defined as a structure that accommodates the mounting substrate, and includes both a resin mold formed integrally with the mounting substrate (semiconductor unit) and a resin case surrounding the mounting substrate (semiconductor unit).

(5) In each of the above-described embodiments, a form in which the semiconductor chip 22 is an RC-IGBT has been exemplified, but the type of the semiconductor chip 22 may be freely changed. For example, the semiconductor chip 22 may be implemented by a single IGBT or FWD. In addition, a metal-oxide-semiconductor field-effect transistor (MOSFET) in which a semiconductor layer is formed of silicon (Si) or silicon carbide (SiC) may be used as the semiconductor chip 22.

(6) The term “n-th” (n is a natural number) in the present application is used merely as a formal and convenient sign (label) to distinguish elements in notation, and does not have any substantive meaning. Therefore, the notation “n-th” should not be construed as limiting the position, manufacturing order, or the like of each element.

### 9. Appendix

For example, the following configurations can be understood from the above-described embodiments.

A semiconductor module according to one aspect (first aspect) of the present disclosure includes: an accommodating member having a first main surface and a second main surface that face opposite directions, and a side surface between the first main surface and the second main surface; a mounting substrate accommodated in the accommodating member; a semiconductor chip mounted to the mounting substrate; and a connection terminal protruding from the side surface, in which the second main surface includes a base surface in which an opening is formed, and a first stepped surface positioned between the base surface and the side surface in plan view and recessed toward the first main surface with respect to the base surface, the mounting substrate has a heat dissipation surface positioned inside the opening, and a first groove recessed toward the first main surface and extending in an extending direction of the side surface is formed in the first stepped surface. In the above aspect, the first groove extending in the extending direction of the side surface of the accommodating member is formed in the second main surface (first stepped surface). Therefore, it is easy to secure a creepage distance between the connection terminal and the heat dissipation surface. In other words, it is possible to reduce a height of the accommodating member (a distance between the first main surface and the base surface) necessary for securing a sufficient creepage distance between the connection terminal and the heat dissipation surface. In addition, the first groove is formed in the first stepped surface recessed toward the first main surface with respect to the base surface in the second main surface of the accommodating member. Therefore, for example, in a configuration in which the base surface and a cooler face each other with a thermally conductive material interposed therebetween, a probability that the thermally conductive material will enter the first groove can be reduced as compared with a configuration in which the first groove is formed in the base surface. Accordingly, shortage of the thermally conductive material between the base surface and the cooler can be suppressed.

In a specific example (second aspect) of the first aspect, a second groove parallel to the first groove is formed in the first stepped surface. In the above aspect, the first groove and the second groove are formed in the first stepped surface of the accommodating member. Therefore, it is easier to secure the creepage distance between the connection terminal and the heat dissipation surface as compared with a configuration in which only the first groove is formed in the first stepped surface. In other words, it is possible to reduce the height of the accommodating member (the distance between the first main surface and the base surface) necessary for securing a sufficient creepage distance between the connection terminal and the heat dissipation surface.

In a specific example (third aspect) of the second aspect, the first groove is shallower than the second groove. In the above aspect, a depth of the first groove is different from a depth of the second groove. Therefore, it is easier to secure both a mechanical strength of the accommodating member and the creepage distance between the connection terminal and the heat dissipation surface as compared with a configuration in which the first groove and the second groove are restricted to the same depth.

In a specific example (fourth aspect) of the first aspect, the second main surface further includes a second stepped surface positioned between the first stepped surface and the side surface in plan view and recessed toward the first main surface with respect to the first stepped surface, and a second groove recessed toward the first main surface and extending in the extending direction of the side surface is formed in the second stepped surface. In the above aspect, the first groove is formed in the first stepped surface, and the second groove is formed in the second stepped surface recessed toward the first main surface with respect to the first stepped surface. Therefore, it is easier to secure the creepage distance between the connection terminal and the heat dissipation surface as compared with a configuration in which only the first groove is formed or a configuration in which both the first groove and the second groove are formed in the first stepped surface. In other words, it is possible to reduce the height of the accommodating member (the distance between the first main surface and the base surface) necessary for securing a sufficient creepage distance between the connection terminal and the heat dissipation surface.

In a specific example (fifth aspect) of any one of the second to fourth aspects, at least one of the first groove or the second groove includes a plurality of portions arranged at intervals in the extending direction of the side surface. According to the above aspect, it is easier to secure the mechanical strength of the accommodating member as compared with a configuration in which the first groove and the second groove are continuous over the entire length of the accommodating member.

In a specific example (sixth aspect) of any one of the first to fifth aspects, a spacing between the base surface and the first stepped surface (for example, height difference) is 1 mm or greater. According to the above aspect, compared with a configuration in which the spacing between the base surface and the first stepped surface is less than 1 mm, the above-described effect of securing the creepage distance between the connection terminal and the surface of the cooler is particularly remarkable.

In a specific example (seventh aspect) of any one of the first to sixth aspects, the first groove includes a plurality of portions arranged at intervals in the extending direction of the side surface. According to the above aspect, it is easier to secure the mechanical strength of the accommodating member as compared with a configuration in which the first groove is continuous over the entire length of the accommodating member.

In a specific example (eighth aspect) of any one of the first to seventh aspects, the first groove is formed spaced from a connection surface between the base surface and the first stepped surface. In the above aspect, the first groove is formed spaced from the connection surface. Therefore, it is easier to secure the creepage distance between the connection terminal and the heat dissipation surface as compared with a configuration in which an inner wall surface of the first groove is continuous with the connection surface. In other words, it is possible to reduce the height of the accommodating member (the distance between the first main surface and the base surface) necessary for securing a sufficient creepage distance between the connection terminal and the heat dissipation surface.

In a specific example (ninth aspect) of any one of the first to seventh aspects, an inner wall surface of the first groove is continuous with a connection surface between the base surface and the first stepped surface. In the above aspect, the inner wall surface of the first groove is continuous with the connection surface. Therefore, a change in shape of the second main surface of the accommodating member is suppressed as compared with a configuration in which the first groove is spaced from the connection surface. Therefore, concentration of stress on the second main surface of the accommodating member can be suppressed.

In a specific example (tenth aspect) of any one of the first to ninth aspects, the first groove is continuous over the entire length of the accommodating member in the extending direction of the side surface. According to the above aspect, since the first groove is continuous over the entire length of the accommodating member, it is easy to secure the creepage distance between the connection terminal and the heat dissipation surface over the entire length of the accommodating member. In other words, it is possible to reduce the height of the accommodating member (the distance between the first main surface and the base surface) necessary for securing a sufficient creepage distance between the connection terminal and the heat dissipation surface.

In a specific example (eleventh aspect) of any one of the first to tenth aspects, the semiconductor module further includes an auxiliary terminal, the side surface includes a first side surface from which the connection terminal protrudes, and a second side surface intersecting the first side surface, the auxiliary terminal protrudes from the second side surface, and the first groove includes a first portion extending in an extending direction of the first side surface, and a second portion continuous with the first portion and extending in an extending direction of the second side surface. In the above aspect, the first groove includes the first portion extending in the extending direction of the first side surface from which the connection terminal protrudes and the second portion extending along the second side surface from which the auxiliary terminal protrudes. Therefore, it is easy to secure a creepage distance between the auxiliary terminal and the heat dissipation surface in addition to the creepage distance between the connection terminal and the heat dissipation surface. In other words, it is possible to reduce the height of the accommodating member (the distance between the first main surface and the base surface) necessary for securing a sufficient creepage distance between the auxiliary terminal and the heat dissipation surface. The side surface 13a and the side surface 13b in each of the above-described aspects are examples of the “first side surface” in the eleventh aspect, and the side surface 13c and the side surface 13d are examples of the “second side surface” in the eleventh aspect.

In a specific example (twelfth aspect) of any one of the first to eleventh aspects, a plurality of connection terminals including the connection terminal protrudes from the side surface, a plurality of side surface grooves extending in a direction from the first main surface toward the second main surface is formed on the side surface between connection terminals adjacent to each other among the plurality of connection terminals, and the first groove is continuous in a direction along the extending direction of the side surface, in a second range corresponding to a first range in which the plurality of side surface grooves is arranged in the direction along the extending direction of the side surface in the accommodating member. In the above aspect, since the side surface groove is formed on the side surface of the accommodating member, it is easy to secure a creepage distance between the connection terminals adjacent to each other. In addition, since the first groove is continuous over the range in which the plurality of side surface grooves is arranged in the accommodating member, it is easy to secure the creepage distance between each connection terminal and the heat dissipation surface. In other words, it is possible to reduce the height of the accommodating member (the distance between the first main surface and the base surface) necessary for securing a sufficient creepage distance between the connection terminal and the heat dissipation surface.

In a specific example (thirteenth aspect) of any one of the first to twelfth aspects, the side surface includes a first side surface and a third side surface that face opposite directions between the first main surface and the second main surface, the connection terminal includes a portion of a connection lead electrically connected to a main electrode of the semiconductor chip, the portion protruding from the first side surface, the second main surface further includes a second stepped surface positioned between the base surface and the third side surface in plan view and recessed toward the first main surface with respect to the base surface, the first stepped surface is a portion positioned between the base surface and the first side surface in plan view and recessed toward the first main surface with respect to the base surface, and no groove is formed in the second stepped surface. Since the connection terminal electrically connected to the main electrode of the semiconductor chip is installed on the first stepped surface of the accommodating member, it is particularly important to secure a sufficient creepage distance between the connection terminal and the heat dissipation surface. According to the thirteenth aspect, since the first groove is formed in the first stepped surface, it is easy to secure the creepage distance between the connection terminal and the heat dissipation surface. On the other hand, the second stepped surface positioned between the base surface and the third side surface in the second main surface is a flat surface in which no groove is formed. Therefore, there is an advantage in that the mechanical strength of the second stepped surface is easily maintained. The side surface 13a in each of the above-described aspects is an example of the “first side surface” in the thirteenth aspect, and the side surface 13b is an example of the “third side surface” in the thirteenth aspect.

A semiconductor module according to one aspect (fourteenth aspect) of the present disclosure includes: an accommodating member including a first main surface and a second main surface that face opposite directions, and a first side surface and a third side surface that face opposite directions between the first main surface and the second main surface; a mounting substrate accommodated in the accommodating member; a semiconductor chip mounted to the mounting substrate; a first connection terminal protruding from the first side surface; and a second connection terminal protruding from the third side surface, in which the second main surface includes: a base surface in which an opening is formed; a first stepped surface positioned between the base surface and the first side surface in plan view and recessed toward the first main surface with respect to the base surface; and a second stepped surface positioned between the base surface and the third side surface in plan view and recessed toward the first main surface with respect to the base surface, the mounting substrate has a heat dissipation surface positioned inside the opening, a first groove recessed toward the first main surface and extending in an extending direction of the first side surface is formed in the first stepped surface, and a second groove recessed toward the first main surface and extending in an extending direction of the third side surface is formed in the second stepped surface. In the above aspect, since the first groove and the second groove are formed in the second main surface (first stepped surface), it is easy to secure the creepage distance from the heat dissipation surface for both the first connection terminal and the second connection terminal. In other words, it is possible to reduce the height of the accommodating member (the distance between the first main surface and the base surface) necessary for securing a sufficient creepage distance between both the first connection terminal and the second connection terminal and the heat dissipation surface. In addition, the first groove and the second groove are formed in the stepped surfaces (first stepped surface and second stepped surface) recessed toward the first main surface with respect to the base surface in the second main surface of the accommodating member. Therefore, for example, in a configuration in which the base surface and the cooler face each other with the thermally conductive material interposed therebetween, a likelihood that the thermally conductive material will enter the first groove or the second groove can be reduced as compared with a configuration in which the first groove and the second groove are formed in the base surface. Accordingly, shortage of the thermally conductive material between the base surface and the cooler can be suppressed. The side surface 13a in each of the above-described aspects is an example of the “first side surface” in the fourteenth aspect, and the side surface 13b is an example of the “third side surface” in the fourteenth aspect.

### DESCRIPTION OF REFERENCE SIGNS

100 semiconductor module

10 accommodating member

11 first main surface

12 second main surface

13(13a, 13b, 13c, 13d) side surface

14 side surface groove

20 semiconductor unit

21 mounting substrate

211 insulating substrate

212 heat dissipation plate

213 conductive pattern

22 semiconductor chip

23 connection lead

24 control lead

25 control chip

26 wire

27a, 27b connection terminal

28a1, 28a2, 28b1, 28b2 auxiliary terminal

31 base surface

311 opening

32a1, 32a2, 32b1, 32b2 stepped surface

33a1, 33a2, 33b1, 33b2 connection surface

34a1, 34a2, 34b1, 34b2 groove

341 inner wall surface

35 each portion of groove

41a, 41b extending region

42a1, 42a2, 42b1, 42b2 end portion region

45a, 45b extending portion

46a1, 46a2, 46b1, 46b2 end portion

90 cooler

91 thermally conductive material

What is claimed is:

1. A semiconductor module comprising:
an accommodating member having a first main surface and a second main surface that face opposite directions, and a side surface between the first main surface and the second main surface;
a mounting substrate accommodated in the accommodating member;
a semiconductor chip mounted to the mounting substrate; and
a connection terminal protruding from the side surface,
wherein:
the second main surface includes:
a base surface in which an opening is formed; and
a first stepped surface positioned between the base surface and the side surface in a plan view and recessed toward the first main surface with respect to the base surface,
the mounting substrate has a heat dissipation surface positioned inside the opening, and
a first groove recessed toward the first main surface and extending in an extending direction of the side surface is formed in the first stepped surface.

2. The semiconductor module according to claim 1, wherein a second groove parallel to the first groove is formed in the first stepped surface.

3. The semiconductor module according to claim 2, wherein the first groove is shallower than the second groove.

4. The semiconductor module according to claim 2, wherein at least one of the first groove or the second groove includes a plurality of portions arranged at intervals in the extending direction of the side surface.

5. The semiconductor module according to claim 1, wherein:
the second main surface further includes a second stepped surface positioned between the first stepped surface and the side surface in the plan view and recessed toward the first main surface with respect to the first stepped surface, and
a second groove recessed toward the first main surface and extending in the extending direction of the side surface is formed in the second stepped surface.

6. The semiconductor module according to claim 5, wherein at least one of the first groove or the second groove includes a plurality of portions arranged at intervals in the extending direction of the side surface.

7. The semiconductor module according to claim 1, wherein a spacing between the base surface and the first stepped surface is 1 mm or greater.

8. The semiconductor module according to claim 1, wherein the first groove includes a plurality of portions arranged at intervals in the extending direction of the side surface.

9. The semiconductor module according to claim 1, wherein the first groove is formed spaced from a connection surface between the base surface and the first stepped surface.

10. The semiconductor module according to claim 1, wherein an inner wall surface of the first groove is continuous with a connection surface between the base surface and the first stepped surface.

11. The semiconductor module according to claim 1, wherein the first groove is continuous over an entire length of the accommodating member in the extending direction of the side surface.

12. The semiconductor module according to claim 1, further comprising an auxiliary terminal, wherein:
the side surface includes:
a first side surface from which the connection terminal protrudes; and
a second side surface intersecting the first side surface,
the auxiliary terminal protrudes from the second side surface, and
the first groove includes:
a first portion extending in an extending direction of the first side surface; and
a second portion continuous with the first portion and extending in an extending direction of the second side surface.

13. The semiconductor module according to claim 1, wherein:
a plurality of connection terminals including the connection terminal protrudes from the side surface,
a plurality of side surface grooves extending in a direction from the first main surface toward the second main surface is formed on the side surface between connection terminals adjacent to each other among the plurality of connection terminals, and
the first groove is continuous in a direction along the extending direction of the side surface, in a second range corresponding to a first range in which the plurality of side surface grooves is arranged in a direction along the extending direction of the side surface in the accommodating member.

14. The semiconductor module according to claim 1, wherein:
the side surface includes a first side surface and a third side surface that face opposite directions between the first main surface and the second main surface,
the connection terminal includes a portion of a connection lead electrically connected to a main electrode of the semiconductor chip, the portion protruding from the first side surface,
the second main surface further includes a second stepped surface positioned between the base surface and the third side surface in the plan view and recessed toward the first main surface with respect to the base surface,
the first stepped surface is a portion positioned between the base surface and the first side surface in the plan view and recessed toward the first main surface with respect to the base surface, and
no groove is formed in the second stepped surface.

15. A semiconductor module comprising:
an accommodating member including a first main surface and a second main surface that face opposite directions, and a first side surface and a third side surface that face opposite directions between the first main surface and the second main surface;
a mounting substrate accommodated in the accommodating member;
a semiconductor chip mounted to the mounting substrate;
a first connection terminal protruding from the first side surface; and
a second connection terminal protruding from the third side surface,
wherein:
the second main surface includes:
a base surface in which an opening is formed;
a first stepped surface positioned between the base surface and the first side surface in a plan view and recessed toward the first main surface with respect to the base surface; and
a second stepped surface positioned between the base surface and the third side surface in the plan view and recessed toward the first main surface with respect to the base surface,
the mounting substrate has a heat dissipation surface positioned inside the opening,
a first groove recessed toward the first main surface and extending in an extending direction of the first side surface is formed in the first stepped surface, and
a second groove recessed toward the first main surface and extending in an extending direction of the third side surface is formed in the second stepped surface.
